(19) United States
(12) Patent Application Publication
(10) Pub. No.: US 2026/0013198 A1
(43) Pub. Date: Jan. 8, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Kouta TOMITA, Nonoichi Ishikawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/939,727

(22) Filed: Nov. 7, 2024

(30) Foreign Application Priority Data
Jul. 3, 2024 (JP) 2024-107657

(51) Int. Cl. H01L 29/417; H01L 29/40; H01L 29/45; H01L 29/47; H01L 29/78

(52) U.S. Cl. CPC H10D 64/252; H10D 30/668; H10D 64/62; H10D 64/64; H10D 64/117

(57) ABSTRACT

A semiconductor device according to an embodiment includes: a first electrode and a second electrode disposed on a first main surface and a second main surface of a semiconductor layer, respectively; a first conductivity type first semiconductor region; a first conductivity type second semiconductor region extending from the first semiconductor region toward the second electrode, and having an upper region having an impurity concentration higher than the first semiconductor region, and a lower region including a region narrower than the upper region; a third electrode disposed in the semiconductor layer via an insulating region and aligned with the lower region along a second direction; a first conductive portion facing the third electrode, electrically connected to the second electrode, and in Schottky contact with the lower region; and a second conductive portion electrically connected to the second electrode and in ohmic contact with the upper region.

### CROSS-REFERENCE TO RELATED APPLICATIONS

This application is based upon and claims the benefit of priority from the prior Japanese Patent Application No. 2024-107657, filed on Jul. 3, 2024; the entire contents of which are incorporated herein by reference.

### FIELD

Embodiments described herein relate generally to a semiconductor device.

### BACKGROUND

A semiconductor device having a switching function, such as a metal oxide semiconductor field effect transistor (MOSFET), is known. In such a semiconductor device, on-resistance is preferably low.

### BRIEF DESCRIPTION OF THE DRAWINGS

FIG. 1 is a cross-sectional view of a semiconductor device according to an embodiment;

FIG. 2 is an enlarged view of a region A1 in FIG. 1;

FIG. 3A is a cross-sectional view for explaining an example of a process of manufacturing the semiconductor device according to the embodiment;

FIG. 3B is a cross-sectional view for explaining the example of the process of manufacturing the semiconductor device according to the embodiment, subsequent to FIG. 3A;

FIG. 3C is a cross-sectional view for explaining the example of the process of manufacturing the semiconductor device according to the embodiment, subsequent to FIG. 3B;

FIG. 3D is a cross-sectional view for explaining the example of the process of manufacturing the semiconductor device according to the embodiment, subsequent to FIG. 3C;

FIG. 3E is a cross-sectional view for explaining the example of the process of manufacturing the semiconductor device according to the embodiment, subsequent to FIG. 3D;

FIG. 3F is a cross-sectional view for explaining the example of the process of manufacturing the semiconductor device according to the embodiment, subsequent to FIG. 3E;

FIG. 4 is a cross-sectional view of a semiconductor device according to Modification 1 of the embodiment;

FIG. 5 is an enlarged view of a region A2 in FIG. 4;

FIG. 6 is a cross-sectional view of a semiconductor device according to Modification 2 of the embodiment;

FIG. 7 is an enlarged view of a region A3 in FIG. 6; and

FIG. 8 is a cross-sectional view of a semiconductor device according to Modification 3 of the embodiment.

### DETAILED DESCRIPTION

A semiconductor device according to an embodiment includes a semiconductor layer, a first electrode, a second electrode, a third electrode, a first semiconductor region, a second semiconductor region, a first conductive portion, and a second conductive portion. The semiconductor layer has a first main surface and a second main surface. The first electrode is disposed on the first main surface. The second electrode is disposed on the second main surface. The first semiconductor region is a first conductivity type semiconductor region disposed in the semiconductor layer and electrically connected to the first electrode. The second semiconductor region is a first conductivity type semiconductor region disposed in the semiconductor layer and extending from the first semiconductor region toward the second electrode. The second semiconductor region includes an upper region including an upper end of the second semiconductor region and having a higher impurity concentration than the first semiconductor region, and a lower region sandwiched between the upper region and the first semiconductor region and including a region narrower than the upper region. The third electrode is disposed in the semiconductor layer via an insulating region, and is aligned with the lower region of the second semiconductor region along a second direction orthogonal to a first direction directed from the first electrode toward the second electrode. The first conductive portion faces the third electrode with the second semiconductor region and the insulating region interposed therebetween, is electrically connected to the second electrode, and is in Schottky contact with the lower region of the second semiconductor region. The second conductive portion is electrically connected to the second electrode and is in ohmic contact with the upper region of the second semiconductor region.

Hereinafter, an embodiment according to the present invention will be described with reference to the drawings. The embodiment does not limit the present invention. The drawings are schematic or conceptual, and a ratio between portions and the like are not necessarily the same as actual ones. In the specification and the drawings, elements similar to those described above regarding the previously described drawings are denoted by the same reference numerals, and detailed description thereof is appropriately omitted.

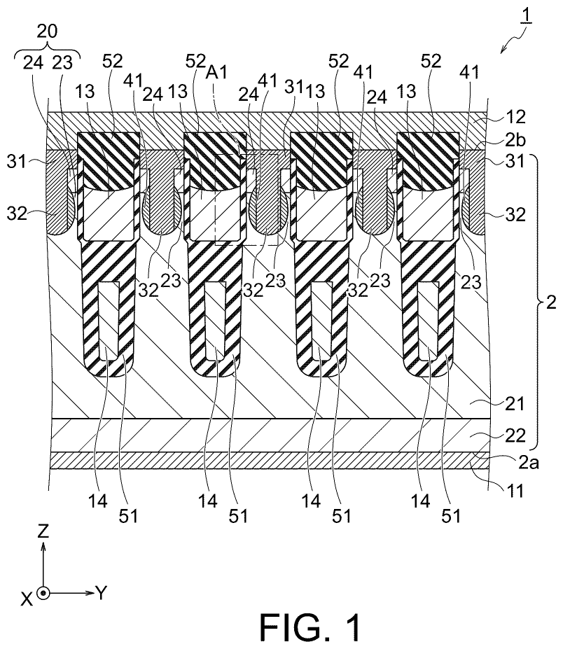

For convenience of description, an XYZ orthogonal coordinate system is adopted as illustrated in FIG. 1 and the like. The Z-axis direction is a stacking direction (thickness direction) in a semiconductor device. In the Z direction, a source electrode side is also referred to as “upper”, and a drain electrode side is also referred to as “lower”. Note that this expression is for convenience and independent of the direction of gravity. The Z-axis direction is the first direction in the claims. The Y-axis direction is the second direction in the claims. The X-axis direction is the third direction in the claims.

In the following description, notations of n⁺, n, n, p⁺, p, and p⁻ may be used to represent a relative level of an impurity concentration in each conductivity type. That is, n⁺ indicates that an n-type impurity concentration is relatively higher than n, and n⁻ indicates that the n-type impurity concentration is relatively lower than n. In addition, p⁺ indicates that a p-type impurity concentration is relatively higher than p, and p⁻ indicates that the p-type impurity concentration is relatively lower than p. When both a p-type impurity and an n-type impurity are contained in each region, each of these notations represents a relative level of a net impurity concentration after these impurities are compensated for each other. The n-type, n⁺-type, and n⁻-type are examples of the first conductivity type in the claims. The p-type, p⁺-type, and p⁻-type are examples of the second conductivity type in the claims. Note that, in the following description, the n-type and the p-type may be inverted. That is, the first conductivity type may be p-type.

An impurity concentration of a semiconductor region can be measured by, for example, secondary ion mass spectrometry (SIMS). A relative level of the impurity concentration can also be determined from a level of a carrier concentration obtained by, for example, scanning capacitance microscopy (SCM).

A dimension such as the width of the conductive portion can be measured by, for example, analysis of a surface and/or a cross section with a transmission electron microscope (TEM), an energy dispersive X-ray spectroscopy (EDX), or a scanning electron microscope (SEM).

In addition, the composition of the conductive portion or the like can be analyzed by EDX or the like.

A semiconductor device 1 according to an embodiment will be described with reference to FIG. 1. FIG. 1 is a cross-sectional view of the semiconductor device 1 according to the embodiment.

The semiconductor device 1 according to the present embodiment is a vertical transistor. More specifically, the semiconductor device 1 is a vertical MOSFET that switches between an on state and an off state by controlling the thickness of a Schottky barrier by controlling a potential of a gate electrode (a gate electrode 13 described later).

As illustrated in FIG. 1, the semiconductor device 1 includes a semiconductor layer 2 having a lower surface 2a and an upper surface 2b, a drain electrode 11 disposed on the lower surface 2a, and a source electrode 12 disposed on the upper surface 2b. Note that the lower surface 2a and the upper surface 2b are examples of the first main surface and the second main surface in the claims, respectively.

Various semiconductor regions described later and the like are disposed in the semiconductor layer 2. The semiconductor layer 2 may be an epitaxial layer, a semiconductor substrate, or a semiconductor substrate and an epitaxial layer disposed on the semiconductor substrate. In the present embodiment, the semiconductor layer 2 is made of silicon (Si). In this case, for example, arsenic (As), phosphorus (P), or antimony (Sb) is be used as an n-type impurity, and for example, boron (B) is used as a p-type impurity. Note that the semiconductor layer 2 may be made of a compound semiconductor such as silicon carbide (SIC) or gallium nitride (GaN).

The drain electrode 11 functions as a drain electrode of the semiconductor device 1. In the present embodiment, the drain electrode 11 is in ohmic contact with a drain region 22 disposed in the semiconductor layer 2. The drain electrode 11 is made of, for example, copper (Cu), titanium (Ti), tungsten (W), or aluminum (Al). The drain electrode 11 is an example of the first electrode in the claims.

The source electrode 12 functions as a source electrode of the semiconductor device 1. In the present embodiment, the source electrode 12 is electrically connected to a drift region 21 via a conductive portion 31 and a conductive portion 32, and is electrically connected to a lower region 23 of the semiconductor layer 2 via the conductive portion 31, the conductive portion 32, and a conductive portion 41. The source electrode 12 is made of, for example, copper (Cu), titanium (Ti), tungsten (W), or aluminum (Al). The source electrode 12 is an example of the second electrode in the claims.

Details of the semiconductor layer 2 will be described. As illustrated in FIG. 1, the gate electrode 13, an FP electrode 14, a thinned region 20, the drift region 21, the drain region 22, the conductive portion 31, the conductive portion 32, the conductive portion 41, and insulating regions 51 and 52 are disposed in the semiconductor layer 2.

The drift region 21 functions as a drift region of the semiconductor device 1. The drift region 21 is disposed on the drain region 22 (above the drain electrode 11). The drift region 21 is, for example, an n⁻-type semiconductor region. An n-type impurity concentration of the drift region 21 is, for example, 1×10¹⁵ cm⁻³ or more and 2×10¹⁶ cm⁻³ or less.

The drain region 22 functions as a drain region of the semiconductor device 1. The drain region 22 is disposed between the drift region 21 and the drain electrode 11, and is electrically connected to the drain electrode 11. The drain region 22 is, for example, an n⁺-type semiconductor region. An n-type impurity concentration of the drain region 22 is, for example, 1×10¹⁸ cm⁻³ or more and 1×10²¹ cm⁻³ or less.

The drift region 21 and the drain region 22 are examples of the first semiconductor region in the claims. Note that the drain region 22 does not have to be disposed. In this case, the drift region 21 is directly disposed on the drain electrode 11, and the drain electrode 11 is electrically connected to the drift region 21. Alternatively, the drift region 21 does not have to be disposed. In this case, for example, the drain region 22 is also disposed at the position of the drift region 21.

The thinned region 20 is a first conductivity type semiconductor region extending from the drift region 21 toward the source electrode 12. The thinned region 20 is an example of the second semiconductor region in the claims. The thinned region 20 has the lower region 23 and an upper region 24. The lower region 23 of the thinned region 20 is sandwiched between the upper region 24 and the drift region 21 in the Z-axis direction, and is sandwiched between the insulating region 51 and the conductive portion 41 in the Y-axis direction. The lower region 23 is, for example, an n⁻-type semiconductor region having almost the same impurity concentration as the drift region 21. In this case, the lower region 23 can also be said to be a portion disposed between the insulating region 51 and the conductive portion 41 in the drift region 21. Note that the lower region 23 is not limited thereto, and may have a higher impurity concentration than the drift region 21 or a lower impurity concentration than the drift region 21.

The upper region 24 of the thinned region 20 is a semiconductor region located on the lower region 23 and including an upper end 24a of the thinned region 20. The upper end 24a of the thinned region 20 is also an upper end of the upper region 24. The upper region 24 has a higher impurity concentration than the drift region 21. In the present embodiment, the upper region 24 has a higher impurity concentration than the lower region 23. The upper region 24 is, for example, an n⁺-type semiconductor region. An n-type impurity concentration of the upper region 24 is, for example, 8×10¹⁹ cm⁻³ or more and 5×10²⁰ cm⁻³ or less.

The gate electrode 13 functions as a gate electrode of the semiconductor device 1. The gate electrode 13 is disposed in the semiconductor layer 2 via the insulating region 51, and is aligned with the lower region 23 along the Y-axis direction orthogonal to a thickness direction (Z-axis direction) of the semiconductor layer 2. The gate electrode 13 is an example of the third electrode in the claims. In the present embodiment, the gate electrode 13 extends in the X-axis direction in FIG. 1. The gate electrode 13 is made of, for example, polysilicon containing a p-type or n-type impurity. The insulating region 51 is an insulating film containing, for example, a silicon oxide or a silicon nitride.

The insulating region 52 is disposed on the gate electrode 13. The insulating region 52 is an interlayer insulating film that electrically insulates the gate electrode 13 from the source electrode 12. The insulating region 52 contains, for example, a silicon oxide or a silicon nitride. Note that the shapes of the insulating region 51 and the insulating region 52 are not limited to the shapes illustrated in FIG. 1. For example, the insulating region 51 may also be disposed on the gate electrode 13, and the insulating region 52 may be disposed on the insulating region 51.

The conductive portion 41 faces the gate electrode 13 with the thinned region 20 and the insulating region 51 interposed therebetween along the Y-axis direction. In the present embodiment, the conductive portion 41 faces the gate electrode 13 with the lower region 23 and the insulating region 51 interposed therebetween along the Y-axis direction. The conductive portion 41 is electrically connected to the source electrode 12 and is in Schottky contact with the lower region 23 of the thinned region 20. In the present embodiment, the conductive portion 41 is not directly connected to the source electrode 12, but is electrically connected to the source electrode 12 via the conductive portion 31 and the conductive portion 32. The conductive portion 41 is an example of the first conductive portion in the claims.

In the present embodiment, the first conductivity type is n-type, and the conductive portion 41 contains a first metal element. The first metal element is at least one of Co, Ni, Se, Rh, Pd, Te, Re, Ir, Pt, and Au. The conductive portion 41 may contain a compound (silicide) of the first metal element and silicon.

A Schottky barrier is formed on a semiconductor side of a boundary surface between the conductive portion 41 and the lower region 23 by a Schottky junction between the conductive portion 41 and the lower region 23. When the Schottky barrier is thick, a current does not substantially flow from the drain electrode 11 to the source electrode 12, and the semiconductor device 1 is turned off. On the other hand, when the Schottky barrier is thin, a current flows from the drain electrode 11 to the source electrode 12, and the semiconductor device 1 is turned on. The semiconductor device 1 can switch between an on state and an off state by controlling the thickness of the Schottky barrier by controlling a potential of the gate electrode 13.

The conductive portion 31 is located on the upper region 24. The conductive portion 31 is electrically connected to the source electrode 12 and is in ohmic contact with the upper region 24 of the thinned region 20. More specifically, the conductive portion 31 is in ohmic contact with an upper end of the upper region 24. The conductive portion 31 is an example of the second conductive portion in the claims.

In the present embodiment, the conductive portion 31 has a work function different from a work function of the conductive portion 41. In addition, in the present embodiment, the first conductivity type is n-type, and the work function of the conductive portion 31 is lower than the work function of the conductive portion 41. The conductive portion 31 contains a second metal element. The second metal element is at least one of Al, Mg, Ti, Se, V, Cr, Mn, Fe, Cu, Zn, Rb, Sr, Y, Zr, Nb, Mo, Ru, Ag, In, Sn, Sb, La, Ce, Pr, Nd, Sm, Eu, Gd, Tb, Dy, Ho, Er, Tm, Yb, Lu, Hf, Ta, W, and Bi. The conductive portion 31 may contain a compound (silicide) of the second metal element and silicon. Note that when the first conductivity type is p-type, the work function of the conductive portion 31 is higher than the work function of the conductive portion 41. In addition, when an ohmic junction can be formed between the conductive portion 31 and the upper region 24 due to a high impurity concentration of the upper region 24 or the like, the work function of the conductive portion 31 may be the same as the work function of the conductive portion 41. In addition, when the first conductivity type is n-type, the work function of the conductive portion 31 may be higher than the work function of the conductive portion 41, and when the first conductivity type is p-type, the work function of the conductive portion 31 may be lower than the work function of the conductive portion 41.

The conductive portion 32 sandwiches the conductive portion 41 together with the thinned region 20 along the Y-axis direction. In the present embodiment, the conductive portion 32 sandwiches the conductive portion 41 together with the lower region 23 along the Y-axis direction. The conductive portion 32 is electrically connected to the source electrode 12 via the conductive portion 31. A lower end of the conductive portion 32 is in Schottky contact with the drift region 21. In the present embodiment, the first conductivity type is n-type, and the work function of the conductive portion 32 is lower than the work function of the conductive portion 41. Therefore, the height of a Schottky barrier between the conductive portion 32 and the drift region 21 is lower than the height of a Schottky barrier between the conductive portion 41 and the lower region 23 of the thinned region 20. The conductive portion 32 is an example of the third conductive portion in the claims. In the present embodiment, the conductive portion 32 is made of the same material as the conductive portion 31. Note that the conductive portion 32 may be made of a material different from that of the conductive portion 31. In this case, the conductive portion 32 may contain, for example, the second metal element or a compound (silicide) of the second metal element and silicon.

In addition, in the present embodiment, the conductive portion 32 is in ohmic contact with at least a part of a side surface of the upper region 24. Note that the conductive portion 31 may extend to the side surface of the upper region 24, and the conductive portion 31 may be in ohmic contact with at least a part of the side surface of the upper region 24. Alternatively, a conductive portion made of a material different from both of the conductive portions 31 and 32 may be disposed, and the conductive portion may be in ohmic contact with at least a part of the side surface of the upper region 24.

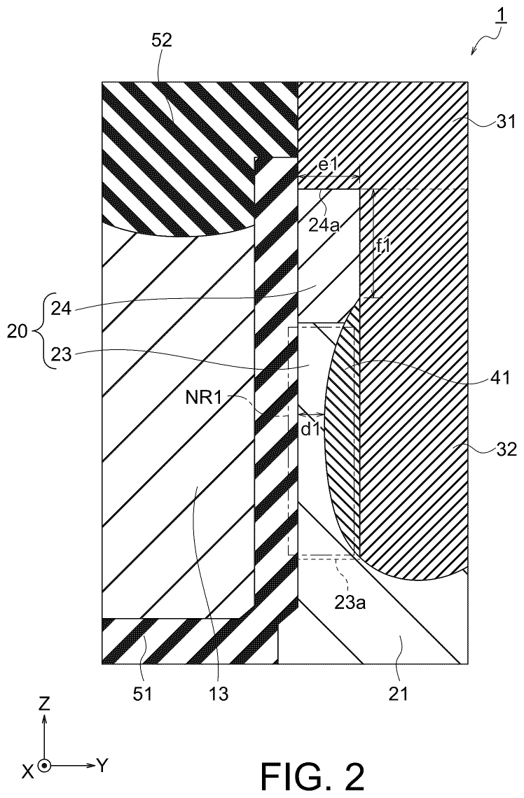

As illustrated in FIGS. 1 and 2, the conductive portion 32 and the conductive portion 41 are disposed in the same trench. This trench is a contact trench reaching the drift region 21 from the upper surface 2b of the semiconductor layer 2. In the present embodiment, the shape of the contact trench in which the conductive portion 32 and the conductive portion 41 are disposed is an elliptical shape.

Note that, in the present embodiment, the drift region 21, the drain region 22, the lower region 23, the upper region 24, the conductive portion 31, the conductive portion 32, and the conductive portion 41 extend along the X-axis direction. In addition, in the present embodiment, the drift region 21, the drain region 22, the lower region 23, the upper region 24, the conductive portion 31, the conductive portion 32, and the conductive portion 41 extend to an end portion, that is, a terminal end (not illustrated) of the semiconductor layer 2 in the X-axis direction. Note that, at the end portion in the X-axis direction, an impurity concentration of the upper region 24 may be lower than an impurity concentration of a portion other than the end portion.

As illustrated in FIG. 1, the semiconductor device 1 according to the present embodiment includes a field plate electrode (FP electrode) 14 disposed in the semiconductor layer 2 via the insulating region 51. In the example of FIG. 1, the FP electrode 14 is disposed below the gate electrode 13, and extends in the X-axis direction. The FP electrode 14 is made of, for example, polysilicon containing a p-type or n-type impurity. The FP electrode 14 is electrically connected to the source electrode 12, and is electrically insulated from the semiconductor layer 2 by the insulating region 51. With such an FP electrode 14, when the semiconductor device 1 is in an off state, a depletion layer extends from the FP electrode 14 to the drift region 21 around the FP electrode 14 by a reverse voltage applied between the drain electrode 11 and the source electrode 12. This depletion layer is connected to a depletion layer of an adjacent FP electrode 14, whereby a withstand voltage of the semiconductor device 1 is improved. Note that the semiconductor device 1 may include an FP electrode disposed in the semiconductor layer 2 via an insulating region (not illustrated) different from the insulating region 51. In addition, the FP electrode 14 may be disposed so as to extend in a direction other than the X-axis direction (for example, the Y-axis direction). The FP electrode 14 does not have to be disposed.

Next, a structure around the thinned region 20 in the present embodiment, that is, the lower region 23, the upper region 24, and the conductive portion 41 will be described in more detail with reference to FIG. 2. FIG. 2 is an enlarged view of a region A1 in FIG. 1.

As illustrated in FIG. 2, when the lower region 23 in the thinned region 20 is viewed along the Z-axis direction, the lower region 23 has a narrow region NR1 which is a region narrower than the upper region 24. In the present embodiment, the length of the narrow region NR1 in the Y-axis direction is shorter than a length e1 of the upper end 24a of the upper region 24 in the Y-axis direction. Here, as illustrated in FIG. 2, a lower end 23a of the lower region 23 has the same height as a lower end of the conductive portion 41.

The narrow region NR1 is at least a part of the lower region 23. In the present embodiment, the entire lower region 23 is configured as the narrow region NR1. In addition, the narrow region NR1 includes a narrowest portion of the narrow region NR1 (hereinafter, also referred to as a “narrowest portion”). In the example of FIG. 2, the narrowest portion has a length d1 in the Y-axis direction. For example, when the semiconductor device 1 is in an off state, the length d1 is equal to or less than a length necessary for preventing a leakage current by a Schottky barrier formed in the vicinity of a boundary surface between the conductive portion 41 and the lower region 23. The length d1 may be equal to or less than the width of a depletion layer formed in the thinned region 20.

The upper region 24 is wider than the narrow region NR1 of the lower region 23. That is, the upper region 24 has a longer length in the Y-axis direction than the narrow region NR1 and the narrowest portion of the lower region 23. More specifically, the upper end 24a of the upper region 24 has a length e1 in the Y-axis direction. The length e1 is longer than the length d1 of the narrowest portion in the Y-axis direction. In addition, the upper region 24 has a length f1 in the Z-axis direction on a side surface in contact with the conductive portion 32. That is, the length f1 is a distance between the upper end 24a of the upper region 24 and an upper end of the conductive portion 41.

The conductive portion 41 is embedded in a recess of the narrow region NR1. That is, a recess having the narrowest portion as a bottom portion in the Y-axis direction is formed in the narrow region NR1, and the conductive portion 41 is embedded in the recess. In other words, a side surface (left side surface in FIG. 2) of the conductive portion 41 on the lower region 23 side is in Schottky contact with the narrow region NR1, and a side surface (right side surface in FIG. 2) of the conductive portion 41 on the conductive portion 32 side is substantially flat from the height of an upper end to the height of a lower end of the conductive portion 41 and is substantially parallel to the Z-axis direction.

In the present embodiment, the narrow region NR1 has a shape in which a width increases as it goes from the narrowest portion having the narrowest width in the narrow region NR1 in an upward direction, and the width increases as it goes from the narrowest portion in a downward direction. In other words, the conductive portion 41 of the present embodiment has a shape in which the width increases from the upper end and then decreases toward the lower end. Specifically, the conductive portion 41 has a shape in which the width increases from the upper end to the height of the narrowest portion and the width decreases from the height of the narrowest portion to the lower end. More specifically, in the present embodiment, the thinned region 20 (the upper region 24 and the lower region 23) has a shape in which a substantially constant width is maintained over the length f1 from the upper end 24a of the upper region 24 to the lower portion of the upper region 24, the width decreases from the lower portion of the upper region 24 to the narrowest portion of the lower region 23, and the width increases from the narrowest portion to the lower end 23a of the lower region 23.

In addition, in the present embodiment, the narrowest portion of the narrow region NR1 is located at a central portion of the narrow region NR1 in the Z-axis direction. In other words, the narrowest portion is located at the height of a central portion of the conductive portion 41 in the Z-axis direction. In other words, a widest portion of the conductive portion 41 is located at the central portion of the conductive portion 41 in the Z-axis direction.

Note that, in FIG. 2, the upper region 24 is illustrated as a region different from the lower region 23, and a boundary between the upper region 24 and the lower region 23 is lower than the position of the upper end of the conductive portion 41. The boundary between the upper region 24 and the lower region 23 is not limited thereto, and for example, may be at the same height as the upper end of the conductive portion 41 or may be higher than the position of the upper end of the conductive portion 41. In practice, an impurity concentration continuously changes along the Z-axis direction, and therefore the boundary between the upper region 24 and the lower region 23 may be unclear. Note that a second conductivity type semiconductor region, for example, a base region is not disposed between the upper region 24 and the lower region 23.

As described above, the semiconductor device 1 according to the first embodiment includes: the first conductivity type thinned region 20 disposed in the semiconductor layer 2 and extending from the drift region 21 toward the source electrode 12, the thinned region 20 including the upper region 24 including the upper end 24a of the thinned region 20 and having a higher impurity concentration than the drift region 21, and the lower region 23 sandwiched between the upper region 24 and the drift region 21 and including the narrow region NR1 narrower than the upper region 24; the gate electrode 13 disposed in the semiconductor layer 2 via the insulating region 51 and aligned with the lower region 23 of the thinned region 20 along the Y-axis direction; the conductive portion 41 facing the gate electrode 13 with the thinned region 20 interposed therebetween along the Y-axis direction, electrically connected to the source electrode 12, and in Schottky contact with the lower region 23 of the thinned region 20; and the conductive portion 31 electrically connected to the source electrode 12 and in ohmic contact with the upper region 24 of the thinned region 20.

According to the present embodiment, since the upper region 24 is wider than the narrow region NR1 of the lower region 23, a contact area between the upper region 24 and the conductive portion 31 increases. More specifically, since the length e1 of the upper end 24a of the upper region 24 in the Y-axis direction is longer than the length d1 of the narrowest portion having the narrowest width in the narrow region NR1 in the Y-axis direction, a contact area between the upper end 24a of the upper region 24 and the conductive portion 31 increases. As a result, contact resistance between the conductive portion 31 and the upper region 24 can be reduced. Therefore, on-resistance of the semiconductor device 1 can be reduced.

In addition, in the present embodiment, the conductive portion 32 is in ohmic contact with at least a part of a side surface of the upper region 24. As a result, the on-resistance of the semiconductor device 1 can be further reduced.

In addition, in the present embodiment, the conductive portion 32 having a lower work function than the conductive portion 41 is in Schottky contact with the drift region 21 at a lower end thereof. As a result, a forward voltage of the semiconductor device 1 can be reduced.

In addition, in the present embodiment, the conductive portion 31 and the upper region 24 extend in the X-axis direction. As a result, an area of ohmic contact between the conductive portion 31 and the upper region 24 increases, and the on-resistance of the semiconductor device 1 can be further reduced. In addition, in the present embodiment, the conductive portion 31 and the upper region 24 extend to an end portion, that is, a terminal end of the semiconductor layer 2 in the X-axis direction. As a result, the area of ohmic contact between the conductive portion 31 and the upper region 24 further increases, and the on-resistance of the semiconductor device 1 can be further reduced.

In addition, in the present embodiment, the conductive portion 32 and the drift region 21 extend in the X-axis direction. As a result, an area of Schottky contact between the conductive portion 32 and the drift region 21 increases, and the forward voltage of the semiconductor device 1 can be further reduced. In addition, in the present embodiment, the conductive portion 32 and the drift region 21 extend to an end portion of the semiconductor layer 2 in the X-axis direction. As a result, the area of Schottky contact between the conductive portion 32 and the drift region 21 further increases, and the forward voltage of the semiconductor device 1 can be further reduced.

### <Method for Manufacturing Semiconductor Device 1>

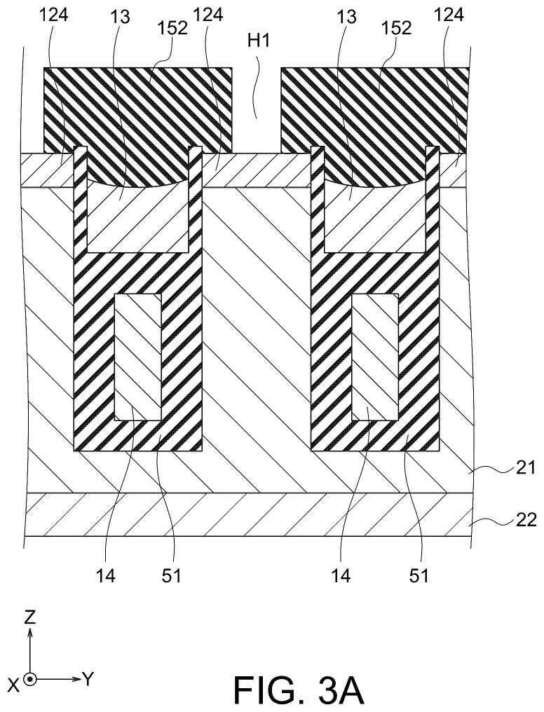

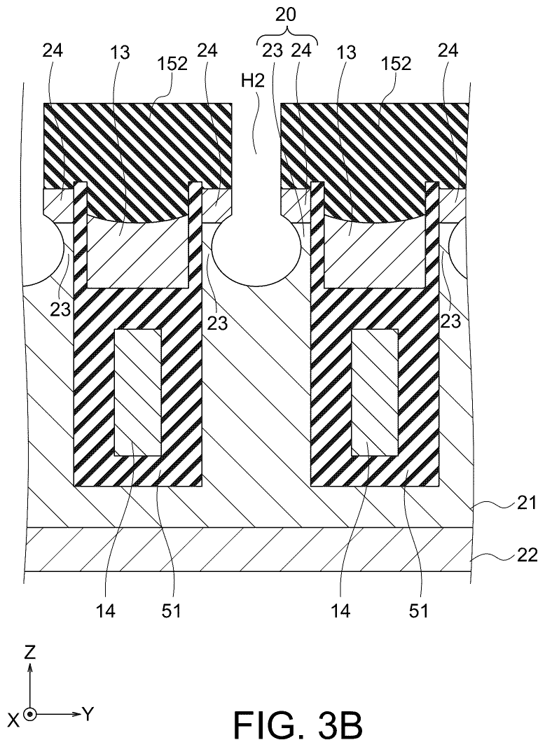

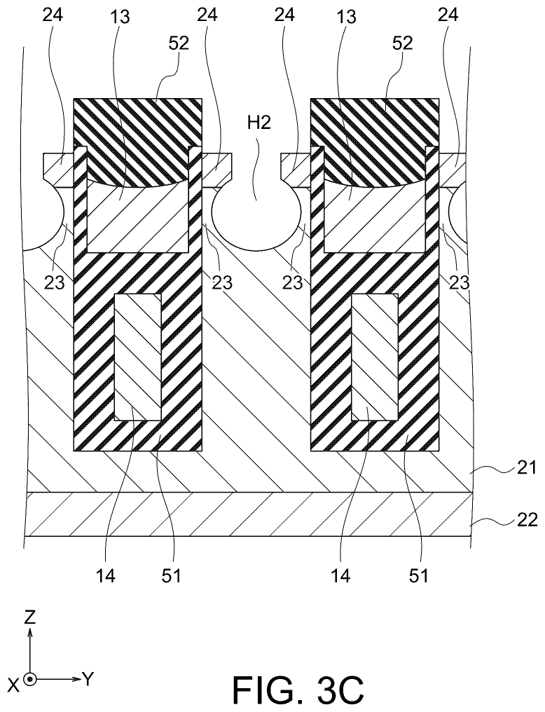

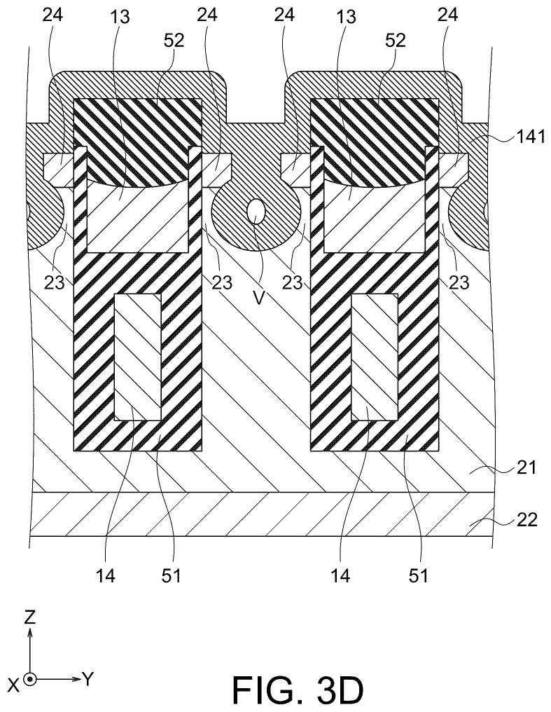

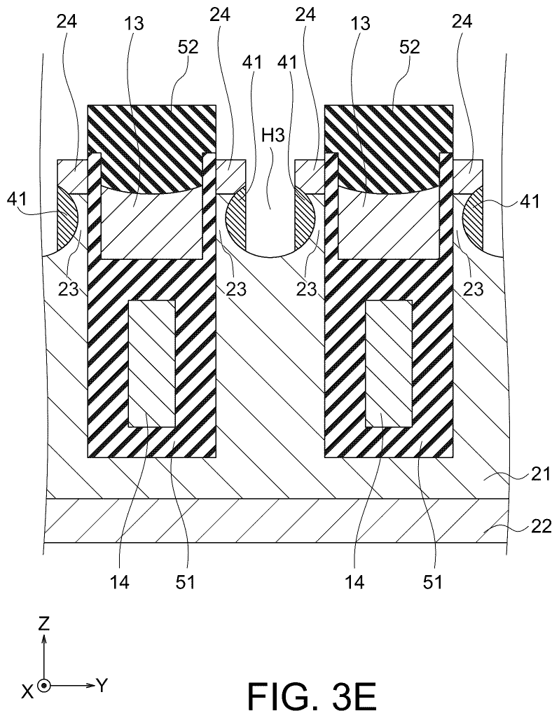

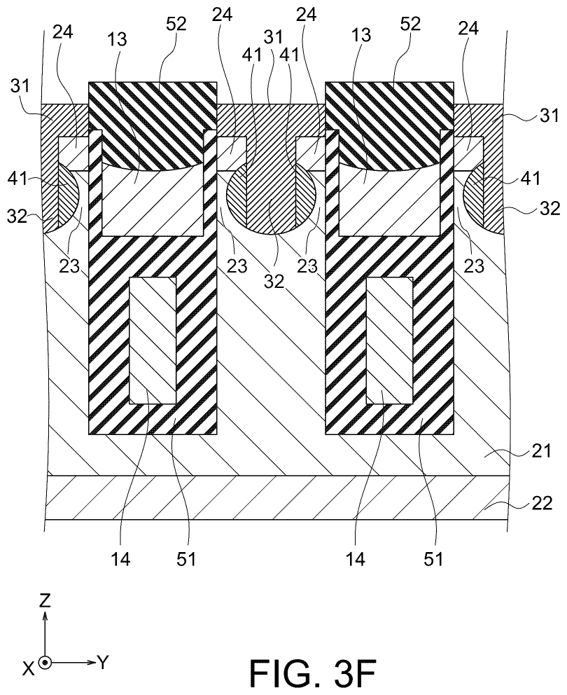

Next, an example of a method for manufacturing the semiconductor device 1 according to the embodiment will be described with reference to FIGS. 3A to 3F. FIGS. 3A to 3F are cross-sectional views for explaining an example of a process of manufacturing the semiconductor device 1 according to the embodiment.

First, a semiconductor layer illustrated in FIG. 3A is prepared. Such a semiconductor layer is obtained, for example, as follows. First, a semiconductor layer including the drain region 22 made of an n⁺-type semiconductor substrate and the drift region 21 made of an n⁻-type epitaxial layer disposed on the drain region 22 is prepared. Thereafter, a trench is formed on an upper surface of the drift region 21 by reactive ion etching (RIE) or the like. This trench is a trench for disposing the gate electrode 13 and the field plate electrode (FP electrode) 14 therein. Thereafter, the insulating region 51 is formed on an inner wall of the trench by thermal oxidation or the like. Thereafter, a conductive material such as polysilicon is deposited in the trench by chemical vapor deposition (CVD) or the like, and surplus of the conductive material is etched back to form the FP electrode 14. Thereafter, an insulating material is deposited so as to embed the FP electrode 14. Thereafter, a conductive material such as polysilicon is deposited on the insulating material by CVD or the like, and surplus of the conductive material is etched back to form the gate electrode 13. Thereafter, ion implantation of an n-type impurity is performed on the upper surface of the drift region 21 to form a high concentration region 124 which is an n⁺-type semiconductor region. Thereafter, an insulating material is deposited so as to embed the gate electrode 13 and to cover an upper surface of the high concentration region 124. Thereafter, a through hole H1 is formed in the insulating material to form an insulating region 152 by RIE or the like. The high concentration region 124 is exposed at a bottom portion of the through hole H1.

Next, as illustrated in FIG. 3B, the high concentration region 124 exposed at the bottom portion of the through hole H1 and a part of the drift region 21 below the high concentration region 124 are removed by RIE or the like using the insulating region 152 as a mask. Thereafter, the drift region 21 is removed toward the gate electrode 13 by performing RIE or the like while changing conditions such as an etching gas type and electric power. As a result, a widened trench H2 is formed in a lower portion. The trench H2 is a trench (contact trench) for disposing the conductive portion 32 and the conductive portion 41 therein. At least a part of the trench H2 has a shape in which a width increases from the upper surface of the semiconductor layer toward a lower side. Through this step, the thinned region 20 is formed. More specifically, the lower region 23 is formed in a portion sandwiched between the insulating region 51 and the trench H2 in the drift region 21, and the high concentration region 124 is divided to form the upper region 24. Note that, instead of performing RIE under different conditions, wet etching or the like may be performed to remove the drift region 21 facing the gate electrode 13 along the Y-axis direction and to increase the width of a lower portion of the contact trench.

Next, as illustrated in FIG. 3C, a part of the insulating region 152 is removed by chemical dry etching (CDE), wet etching, or the like. More specifically, the insulating region 152 located above the upper region 24 is removed. In addition, the thickness of the insulating region 152 located on the gate electrode 13 also decreases. A portion of the insulating region 152 remaining without being removed corresponds to the insulating region 52.

Next, as illustrated in FIG. 3D, the inside of the trench H2 is filled with a conductive material of the first metal element by CVD or the like, and the conductive material is also deposited on an upper surface of the semiconductor layer. As a result, a conductive portion 141 is formed. Note that, as illustrated in FIG. 3D, a void V may be formed in the conductive portion 141.

Next, as illustrated in FIG. 3E, a part of the conductive portion 141 is removed by RIE or the like. More specifically, a portion deposited on the insulating region 52, a portion deposited on the upper region 24, a portion sandwiched between the left and right upper regions 24 in the trench H2, and a portion located below the portion in the conductive portion 141 are removed. As a result, a trench H3 and the conductive portion 41 are formed. The conductive portion 41 is a part of the conductive portion 141 remaining in a recess of the lower region 23. Note that a part of the conductive portion 141 may remain at a bottom portion of the trench H3.

Next, as illustrated in FIG. 3F, the inside of the trench H3 is filled with a conductive material of the second metal element by CVD or the like, and the conductive material is also deposited on an upper surface of the semiconductor layer. As a result, the conductive portion 31 and the conductive portion 32 are formed. More specifically, the conductive portion 32 filling the trench H3 is formed, and the conductive portion 31 is formed on the upper region 24 and the insulating region 52. Thereafter, the conductive portion 31 is removed from an upper portion of the insulating region 52 by CDE or the like.

Thereafter, although not illustrated, the drain electrode 11 is formed on a lower surface of the semiconductor layer, and the source electrode 12 is formed on an upper surface of the semiconductor layer.

Through the above steps, the semiconductor device 1 is manufactured.

According to the manufacturing method of the present embodiment, the width of the upper region 24 can be maintained while the widths of the narrow region NR1 and the narrowest portion of the lower region 23 are reduced. Therefore, an impurity concentration of a portion of the upper region 24 in contact with the conductive portion 31 can be maintained high, and contact resistance between the conductive portion 31 and the upper region 24 can be reduced.

In addition, according to the manufacturing method of the present embodiment, even when a void V is formed in the conductive portion 141, the void V is removed in a subsequent step, and therefore the semiconductor device 1 can be stably manufactured.

In addition, in the manufacturing method of the present embodiment, the conductive portion 32 is made of the same material as the conductive portion 31. As a result, the process of manufacturing the semiconductor device 1 can be simplified.

Note that, as illustrated in FIG. 3F, in the manufacturing method of the present embodiment, a portion of a side surface of the conductive portion 32 in contact with the upper region 24 (a portion having the length f1 in FIG. 2) is parallel to the Z-axis direction. The portion is not limited thereto, and may be inclined so as to be wider as it goes an upper side (source electrode 12 side). As a result, conditions such as RIE for forming the trench H2 illustrated in FIG. 3B are relaxed, and formation of the trench H2 is facilitated. Note that the length e1 of the upper end 24a of the upper region 24 illustrated in FIG. 2 in the Y-axis direction is shortened by the inclination, and therefore the degree of the inclination is within a range in which an increase in contact resistance between the upper region 24 and the conductive portion 31 does not cause a problem.

Note that the shape of the contact trench in which the conductive portion 32 and the conductive portion 41 are disposed is not limited to the above-described shape. Hereinafter, Modifications 1 to 3 in which the shape of the contact trench is changed will be described. Also in each of Modifications described below, on-resistance of a semiconductor device can be reduced similarly to the above embodiment.

### Modification 1

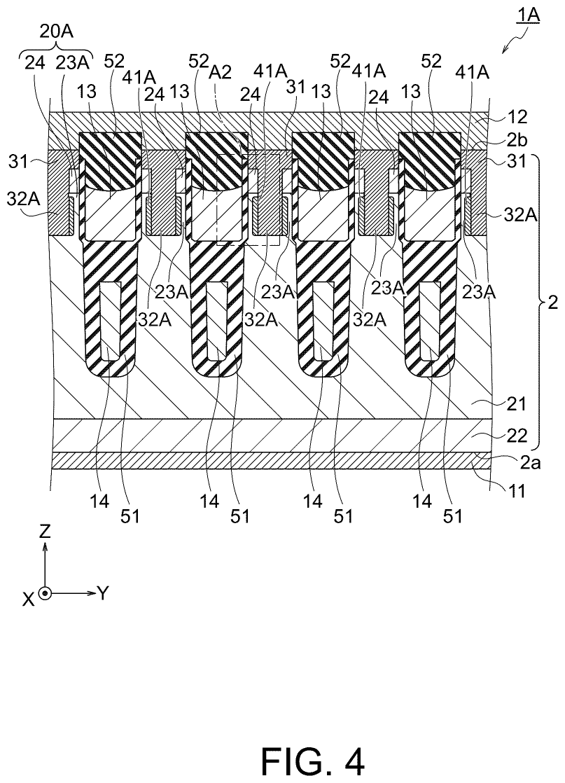

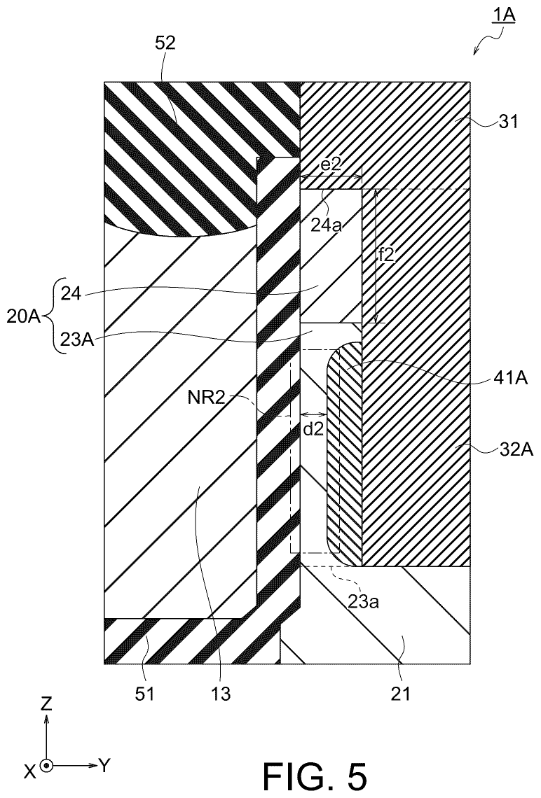

A semiconductor device 1A according to Modification 1 of the embodiment will be described with reference to FIGS. 4 and 5. FIG. 4 is a cross-sectional view of the semiconductor device 1A according to the present Modification. FIG. 5 is an enlarged view of a region A2 in FIG. 4. In the present Modification, the shape of a contact trench in which a conductive portion 32A and a conductive portion 41A are disposed is a so-called bottle shape.

As illustrated in FIG. 5, a thinned region 20A of the present Modification has a lower region 23A and the upper region 24. The lower region 23A has a narrow region NR2 narrower than the upper end 24a of the upper region 24. The narrow region NR2 includes a narrowest portion having the narrowest width in the narrow region NR2. The narrowest portion has a length d2 in the Y-axis direction. In the present Modification, the narrowest portion is a region extending along the Z-axis direction. The conductive portion 41A is embedded in a recess of the narrow region NR2.

The upper region 24 is wider than the narrow region NR2 of the lower region 23A. More specifically, the upper end 24a of the upper region 24 has a length e2 in the Y-axis direction. The length e2 is longer than the length d2 of the narrowest portion in the Y-axis direction. In addition, the upper region 24 has a length f2 in the Z-axis direction on a side surface in contact with the conductive portion 32A. That is, the length f2 is a distance between the upper end 24a of the upper region 24 and a lower end of the upper region 24.

In the present Modification, the narrow region NR2 of the lower region 23A has a shape in which a width increases as it goes from the narrowest portion having the narrowest width in the narrow region NR2 in an upward direction, and the width increases as it goes from the narrowest portion in a downward direction. Note that the narrowest portion of the present Modification has a predetermined length along the Z-axis direction. In other words, the conductive portion 41A of the present Modification has a shape in which a width increases from an upper end, then the same width is maintained over a predetermined length of the conductive portion 41A along the Z-axis direction, and then the width decreases toward a lower end. Specifically, the conductive portion 41A has a shape in which the width increases from the upper end to the height of the narrowest portion, then the same width is maintained over a predetermined length of the conductive portion 41A along the Z-axis direction, and then the width decreases toward the lower end. More specifically, the lower region 23A and the upper region 24 of the present Modification have a shape in which a substantially constant width is maintained over a predetermined length from the upper end 24a of the upper region 24 to an upper portion of the lower region 23A, then the width decreases from the upper portion of the lower region 23A to the narrowest portion, then the same width is maintained over a predetermined length along the Z-axis direction, and then the width increases toward a lower end 23a of the lower region 23A. In the example of FIG. 5, the narrow region NR2 of the lower region 23A maintains the same length d2 in the Y-axis direction over a length equal to or more than half of the length of the narrow region NR2 in the Z-axis direction. In other words, the conductive portion 41A maintains the same width over a length equal to or more than half of the length of the lower region 23A in the Z-axis direction. Note that, in the example of FIG. 5, a bottom surface of the conductive portion 32A is substantially flat along the Y-axis direction.

The lower region 23A and the conductive portions 32A and 41A of the present Modification can be manufactured, for example, by changing conditions of RIE when the trench H2 is formed from the conditions in the above-described embodiment.

### Modification 2

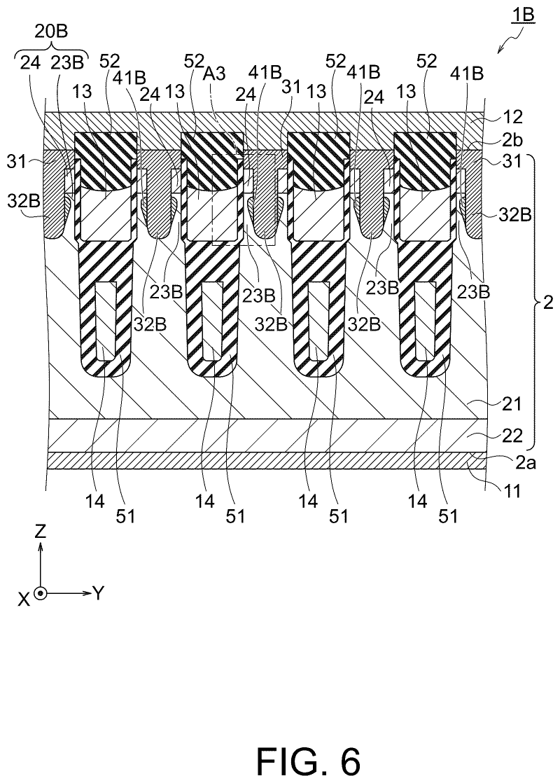

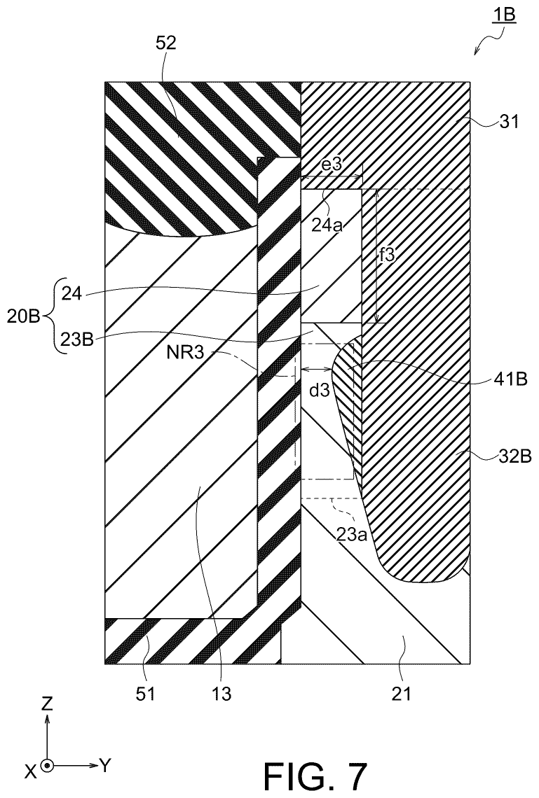

Next, a semiconductor device 1B according to Modification 2 of the embodiment will be described with reference to FIGS. 6 and 7. FIG. 6 is a cross-sectional view of the semiconductor device 1B according to the present Modification. FIG. 7 is an enlarged view of a region A3 in FIG. 6. In the present Modification, the shape of a contact trench in which a conductive portion 32B and a conductive portion 41B are disposed is a so-called carrot shape.

As illustrated in FIG. 7, a thinned region 20B of the present Modification has a lower region 23B and the upper region 24. The lower region 23B has a narrow region NR3 narrower than the upper end 24a of the upper region 24. The narrow region NR3 includes a narrowest portion having the narrowest width in the narrow region NR3. The narrowest portion has a length d3 in the Y-axis direction. The conductive portion 41B is embedded in a recess of the narrow region NR3.

The upper region 24 is wider than the narrow region NR3 of the lower region 23B. More specifically, the upper end 24a of the upper region 24 has a length e3 in the Y-axis direction. The length e3 is longer than the length d3 of the narrowest portion in the Y-axis direction. In addition, the upper region 24 has a length f3 in the Z-axis direction on a side surface in contact with the conductive portion 32B. That is, the length f3 is a distance between the upper end 24a of the upper region 24 and a lower end of the upper region 24.

In the present Modification, the narrow region NR3 of the lower region 23B has a shape in which a width increases as it goes from the narrowest portion having the narrowest width in the narrow region NR3 in an upward direction, and the width increases as it goes from the narrowest portion in a downward direction. In other words, the conductive portion 41B of the present Modification has a shape in which a width increases from an upper end to the height of the narrowest portion and the width decreases from the height of the narrowest portion to a lower end. More specifically, the lower region 23B and the upper region 24 of the present Modification have a shape in which a substantially constant width is maintained over a predetermined length from the upper end 24a of the upper region 24 to an upper portion of the lower region 23B, the width decreases from the upper portion of the lower region 23B to the narrowest portion, and the width increases from the narrowest portion to a lower end 23a of the lower region 23B. Note that, in the example of FIG. 7, the conductive portion 32B has a substantially flat slope from the height of the narrowest portion to a bottom surface.

In the present Modification, the narrowest portion of the lower region 23B is located at an upper portion of the narrow region NR3 in the Z-axis direction. In other words, the narrowest portion is located at a height higher than a center of the conductive portion 41B in the Z-axis direction. In other words, a widest portion of the conductive portion 41B is located above a center of the conductive portion 41B in the Z-axis direction.

The lower region 23B and the conductive portions 32B and 41B of the present Modification can be manufactured, for example, by changing conditions when the trench H2 is formed from the conditions in the embodiment.

### Modification 3

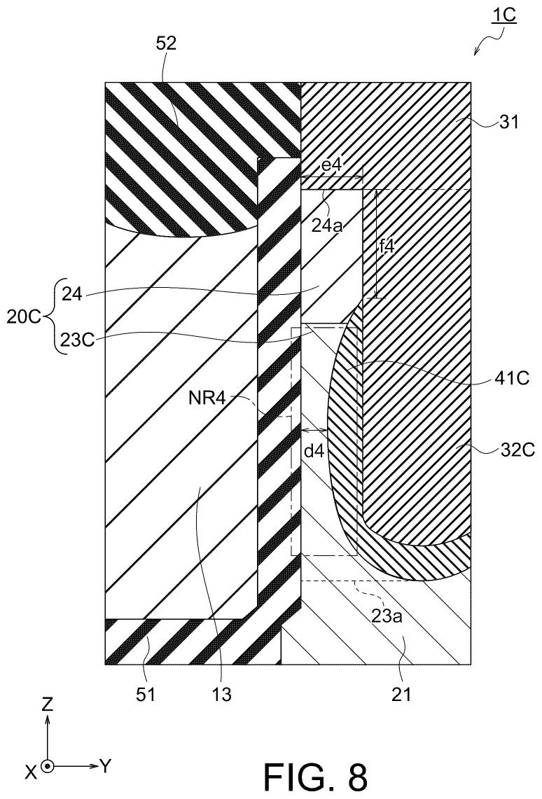

Next, a semiconductor device 1C according to Modification 3 of the embodiment will be described with reference to FIG. 8. FIG. 8 is a cross-sectional view of the semiconductor device 1C according to the present Modification, and corresponds to an enlarged view of a region A1 in FIG. 1. In the present Modification, the conductive portion 41 in the embodiment is also disposed between the conductive portion 32 and the drift region 21.

When the semiconductor device 1C is manufactured, in the step of removing the conductive portion 141 illustrated in FIG. 3D, referred to in the description regarding the method of manufacturing the semiconductor device 1, the conductive portion 141 is left inside the recess of the lower region 23 and at the bottom portion of the trench H3. The conductive portion 41C of the present Modification corresponds to a portion remaining in the recess of the lower region 23 of the conductive portion 141 and at the bottom portion of the trench H3. The conductive portion 32C of the present Modification is not electrically connected to the drift region 21.

As illustrated in FIG. 8, a thinned region 20C of the present Modification has a lower region 23C and the upper region 24. The conductive portion 41C has a portion embedded in a bottom portion of a contact trench (between the conductive portion 32 and the drift region 21) in addition to a portion embedded in the recess of the lower region 23C. On the other hand, the lower region 23C of the present Modification is the same as the lower region 23 of the embodiment except for the position of the lower end 23a. In addition, similarly to the embodiment, the lower region 23C has a narrow region NR4 narrower than the upper end 24a of the upper region 24. The narrow region NR4 includes a narrowest portion having the narrowest width in the narrow region NR4. The narrowest portion has a length d4 in the Y-axis direction. In the upper region 24, the upper end 24a has a length e4 in the Y-axis direction. A length f4 is a distance between the upper end 24a of the upper region 24 and an upper end of the conductive portion 41C.

In the above-described embodiments and Modifications, some shapes of the contact trench, that is, some shapes of the narrow region included in the lower region have been described. On the other hand, the shape of the narrow region is not limited thereto. For example, the narrow region may have a shape in which a width increases from a narrowest portion having the narrowest width in the narrow region in an upward direction, the width increases as it goes from the narrowest portion in a downward direction, and the narrowest portion is located at a lower portion of the narrow region in the Z-axis direction. In addition, in the embodiment and Modifications described above, the lower region has one narrow region. The lower region is not limited thereto, and may have a plurality of narrow regions.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a semiconductor layer having a first main surface and a second main surface;
a first electrode disposed on the first main surface;
a second electrode disposed on the second main surface;
a first conductivity type first semiconductor region disposed in the semiconductor layer and electrically connected to the first electrode;
a first conductivity type second semiconductor region disposed in the semiconductor layer, extending from the first semiconductor region toward the second electrode, and having an upper region including an upper end of the second semiconductor region and having an impurity concentration higher than the first semiconductor region, and a lower region sandwiched between the upper region and the first semiconductor region and including a region narrower than the upper region;
a third electrode disposed in the semiconductor layer via an insulating region and aligned with the lower region of the second semiconductor region along a second direction orthogonal to a first direction directed from the first electrode toward the second electrode;
a first conductive portion facing the third electrode with the second semiconductor region and the insulating region interposed therebetween, electrically connected to the second electrode, and in Schottky contact with the lower region of the second semiconductor region; and
a second conductive portion electrically connected to the second electrode and in ohmic contact with the upper region of the second semiconductor region.

2. The semiconductor device according to claim 1, wherein the first conductive portion is embedded in a recess of the region of the second semiconductor region.

3. The semiconductor device according to claim 1, wherein the region of the second semiconductor region has a shape in which a width increases from a narrowest portion in the region in an upward direction, and the width increases from the portion in a downward direction.

4. The semiconductor device according to claim 3, wherein the portion is located at a height of a central portion of the first conductive portion in the first direction.

5. The semiconductor device according to claim 3, wherein the portion has a predetermined length along the first direction.

6. The semiconductor device according to claim 3, wherein the portion is located above a center of the first conductive portion in the first direction.

7. The semiconductor device according to claim 1, wherein the first conductive portion has a shape in which a width increases from an upper end and then decreases toward a lower end.

8. The semiconductor device according to claim 7, wherein a widest portion of the first conductive portion is located at a height of a central portion of the first conductive portion in the first direction.

9. The semiconductor device according to claim 7, wherein the first conductive portion has a shape in which the width increases from the upper end, then a same width is maintained over a predetermined length of the first conductive portion along the first direction, and then the width decreases toward the lower end.

10. The semiconductor device according to claim 7, wherein the widest portion of the first conductive portion is located above a center of the first conductive portion in the first direction.

11. The semiconductor device according to claim 1, further comprising a third conductive portion sandwiching the first conductive portion together with the second semiconductor region along the second direction and electrically connected to the second conductive portion.

12. The semiconductor device according to claim 11, wherein a lower end of the third conductive portion is in Schottky contact with the first semiconductor region, and a height of a Schottky barrier between the third conductive portion and the first semiconductor region is lower than a height of a Schottky barrier between the first conductive portion and the lower region.

13. The semiconductor device according to claim 12, wherein the third conductive portion is made of a same material as the second conductive portion.

14. The semiconductor device according to claim 12, wherein the third conductive portion and the first semiconductor region extend along a third direction orthogonal to the first direction and the second direction.

15. The semiconductor device according to claim 11, wherein the first conductive portion is electrically connected to the second electrode via the third conductive portion.

16. The semiconductor device according to claim 1, wherein the second conductive portion and the upper region of the second semiconductor region extend along a third direction orthogonal to the first direction and the second direction.

17. The semiconductor device according to claim 1, wherein a second conductivity type semiconductor region is not disposed between the upper region and the lower region of the second semiconductor region.

18. The semiconductor device according to claim 1, wherein the semiconductor device is a vertical MOSFET that switches between an on state and an off state by controlling a thickness of a Schottky barrier by controlling a potential of the third electrode.

19. The semiconductor device according to claim 1, wherein the first conductivity type is n-type, and the second conductive portion has a work function lower than the first conductive portion.

20. The semiconductor device according to claim 19, wherein
the first conductive portion contains a first metal element, and the first metal element is at least one of Co, Ni, Se, Rh, Pd, Te, Re, Ir, Pt, and Au, and
the second conductive portion contains a second metal element, and the second metal element is at least one of Al, Mg, Ti, Se, V, Cr, Mn, Fe, Cu, Zn, Rb, Sr, Y, Zr, Nb, Mo, Ru, Ag, In, Sn, Sb, La, Ce, Pr, Nd, Sm, Eu, Gd, Tb, Dy, Ho, Er, Tm, Yb, Lu, Hf, Ta, W, and Bi.
